(19) United States
(12) Patent Application Publication
(10) Pub. No.: US 2026/0150378 A1
(43) Pub. Date: May 28, 2026

(54) APPARATUS INCLUDING GATE STRUCTURE ON SEMICONDUCTOR SUBSTRATE

(71) Applicant: MICRON TECHNOLOGY, INC., BOISE, ID (US)

(72) Inventor: Yoshikazu Moriwaki, Hiroshima (JP)

(73) Assignee: MICRON TECHNOLOGY, INC., Boise, ID (US)

(21) Appl. No.: 19/394,613

(22) Filed: Nov. 19, 2025

Related U.S. Application Data
(60) Provisional application No. 63/725,945, filed on Nov. 27, 2024.

(51) Int. Cl. H10D 64/66; H10D 30/68; H10D 84/85; H10W 74/10

(52) U.S. Cl. CPC H10D 64/675; H10D 30/6891; H10D 84/856; H10W 74/137

(57) ABSTRACT

Some embodiments of the disclosure provide an apparatus comprising a gate structure on a semiconductor substrate and a layered buffer on the gate structure. The layered buffer includes a first buffer layer including an oxide, and a second buffer layer including for example a nitride under the first buffer layer, capable of preventing ingress of oxygen from the first buffer, oxide layer to the gate structure. In the case of a CMOS device, an NMOS transistor may include a tensor stressor layer on the gate structure. The layered buffer may be provided between the gate structure and the tensor stressor layer.

### CROSS-REFERENCE TO RELATED APPLICATIONS

This application claims the filing benefit of U.S. Provisional Application No. 63/725,945, filed Nov. 27, 2024. This application is incorporated by reference herein in its entirety and for all purposes.

### BACKGROUND

High data reliability, high speed of memory access, low power consumption, and reduced chip size are some features that are demanded from semiconductor memory devices, such as a dynamic random-access memory (DRAM). Transistors, such as field-effect transistors (FETs), included in semiconductor memory devices may include a tensile stressor as a mobility booster to strain channels and improve carrier mobilities.

### BRIEF DESCRIPTION OF THE DRAWINGS

FIG. 1 depicts an example configuration of at least part of a semiconductor device in a cross-sectional view according to some embodiments of the disclosure.

FIG. 2 is an enlarged view of part of the example configuration depicted in FIG. 1 according to some embodiments of the disclosure.

FIG. 3 depicts an example configuration of at least part of a semiconductor device in a cross-sectional view according to some embodiments of the disclosure.

FIG. 4 depicts an example configuration of at least part of a semiconductor device in a cross-sectional view according to some embodiments of the disclosure.

### DETAILED DESCRIPTION

Various example embodiments of the disclosure will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for ease of illustration. In the drawings, the dimensions and dimensional ratios of each unit do not necessarily match the actual dimensions and dimensional ratios in the embodiments.

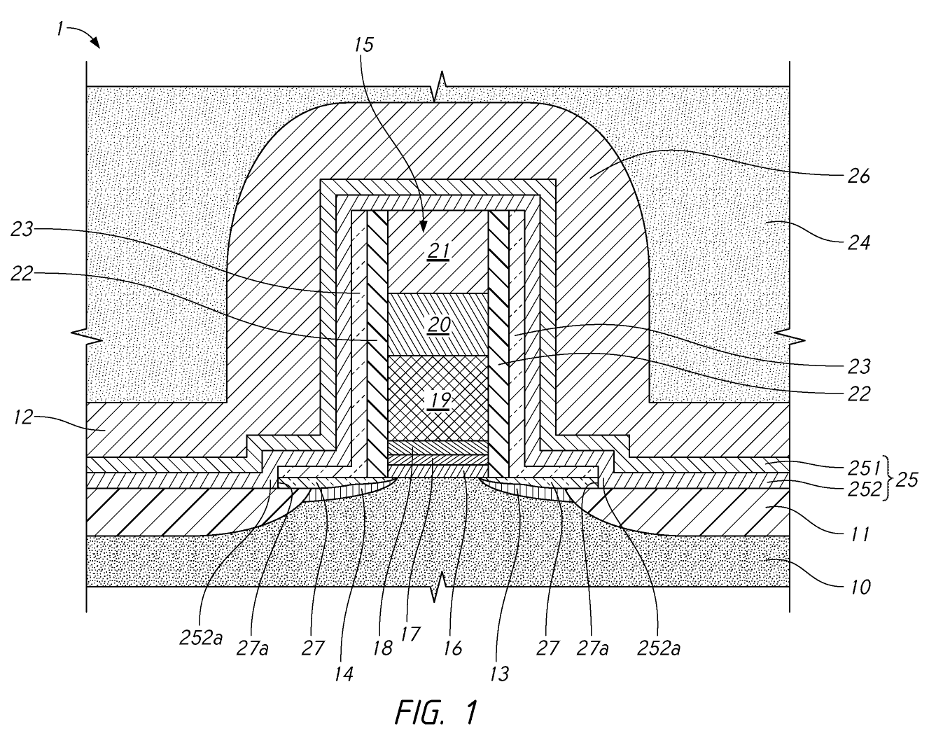

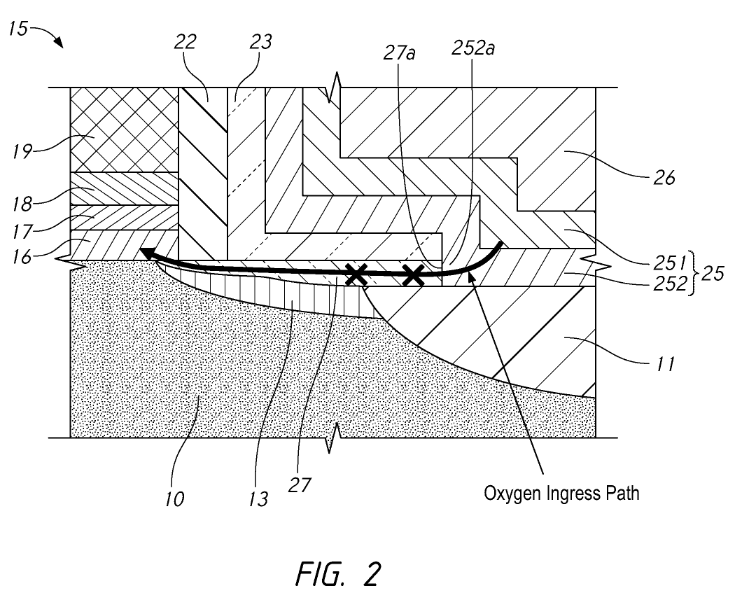

FIG. 1 depicts an example configuration of at least part of a semiconductor device 1 in a cross-sectional view according to some embodiments of the disclosure. FIG. 2 is an enlarged view of part of the example configuration depicted in FIG. 1 according to some embodiments of the disclosure. The semiconductor device 1 may be one example of an apparatus. The semiconductor device 1 may be a dynamic random-access memory (DRAM). In the example configuration, the semiconductor device 1 includes one or more transistor structures, each including active regions 11 and 12 that are adjacent to lightly-doped regions 13 and 14, respectively, as source/drain regions, formed in a semiconductor substrate 10, and further including a gate structure 15 above a channel region between the active regions 11 and 12. In some instances, The semiconductor device 1 may include a plurality of memory mats arranged in a matrix on the semiconductor substrate 10. Each memory mat may include a plurality of memory cells at intersections of word lines arranged in row and bit lines arranged in column in a memory cell region. The memory mat may include a driver region and a sense amplifier region adjacent to the memory cell region. The driver region may be on sides of the memory cell region in a direction of the word lines (row), and includes, for example, subword drivers, row decoders, and row address latches, each of which uses one or more transistors or transistor structures. The sense amplifier region may be on sides of the memory cell region in a direction of the bit lines (column), and includes, for example, sense amplifiers, column decoders, and column address latches, each of which includes one or more transistors or transistor structures.

The gate structure 15 includes a gate stack with multiple layers stacked on one another on a surface of the semiconductor substrate 10. In the example structure, the gate stack includes a buffer layer 16, a high-k layer 17, a metal gate layer 18, a buffer layer 19, a metal layer 20, and a cap layer 21 stacked on one another in that order on a surface of the semiconductor substrate 10. The buffer layer 16 may be an insulating layer, and may include an insulating material, such as silicon oxide (SiO). The buffer layer 16 may be an oxide layer. The buffer layer 16 may also be referred to as a gate oxide layer. The high-k layer 17 may include a high-k dielectric material, such as hafnium oxide (HfO). The high-k material may have a dielectric constant greater than the insulating material of the buffer layer 16. The metal gate layer 18 may include a metal alloy material, such as titanium nitride (TiN). The buffer layer 19 may include a silicon-containing material, such as polycrystalline silicon or polysilicon (poly-Si). The metal layer 20 may include a low resistive metal, such as tungsten (W). The cap layer 21 may be an insulating layer, and may include an insulating material, such as silicon nitride (SiN).

The gate structure 15 further includes a side wall on the gate stack. The side wall includes a double-wall structure which includes a first side wall 22 on a side surface of the gate stack and a second side wall 23 on the first side wall 22. The first side wall 22 may include, for example, silicon nitride. The second side wall 23 may include, for example, silicon nitride. The side walls 22 and 23 each may be a spacer that covers at least the side surfaces of the gate structure 15 and at least partially the lightly-doped regions 13 and 14 and the active regions 11 and 12.

To provide the gate structure 15 including the side wall on the surface of the semiconductor substrate 10, first, the multi layers 16-21 are provided on the entire surface of the semiconductor substrate 10 in that order, and then portions thereof are etched to form the gate stack having a predetermined profile. Subsequently, the first side wall 22 is formed on a side surface of the gate stack by, for example, deposition and etching. Then, the second side wall 23 is formed on the first side wall 22 by, for example, deposition and etching. Conventional deposition and etching techniques may be used as appropriate. In the example configuration, the gate structure 15 including the side wall is embedded in an interlayer 24 on the surface of the semiconductor substrate 10. The interlayer 24 may be an oxide layer including an oxide material, such as silicon oxide.

In the present embodiments, the semiconductor device 1 further includes a layered buffer 25 on the gate structure 15. The layered buffer 25 includes a first buffer layer 251 and a second buffer layer 252 under the first buffer layer 251.

The first buffer layer 251 includes an oxide. The first buffer layer 251 is an oxide layer. In some embodiments, the first buffer layer 251 may include silicon oxide (SiO). In some embodiments, the first buffer layer 251 may include silicon oxycarbonitride (SiOCN), that is a low-k dielectric material. In some embodiments, the first buffer layer 251 may include other oxide materials, such as silicon oxynitride (SiON) and silicon oxycarbide (SiOC). The first buffer layer 251 may include at least one of SiO, SiOCN, SiON, or SiOC. The first buffer layer 251 may be an etching stopper layer (may also be referred to as an etch stop layer). The first buffer layer 251 may be a stopper layer for an etching process that removes a tensile stressor layer 26. The tensile stressor layer 26 may be a nitrogen layer, such as a silicon nitride layer. In a case of a complementary metal-oxide-semiconductor (CMOS) device, a tensile stressor layer may be first formed on both a gate structure of an n-channel MOS (NMOS) transistor and a gate structure of a p-channel NMOS (PMOS) transistor, and then, while the tensile stressor layer may be left on the NMOS transistor gate structure to improve electron mobility, the tensile stressor layer may be removed from the PMOS transistor gate structure by for example dry etching because the tensile stressor layer may deteriorate hole mobility. The oxide buffer layer 251 is hence provided as an etching stopper layer to stop the etching from removing the layers or films under the tensile stressor layer 26. In some embodiments, the layer 251 may be part of the side wall of the gate structure 15. In some embodiments, the layered buffer 25 including the layer 251 and the layer 252 (which will be described in further detail below) may be part of the side wall of the gate structure 15.

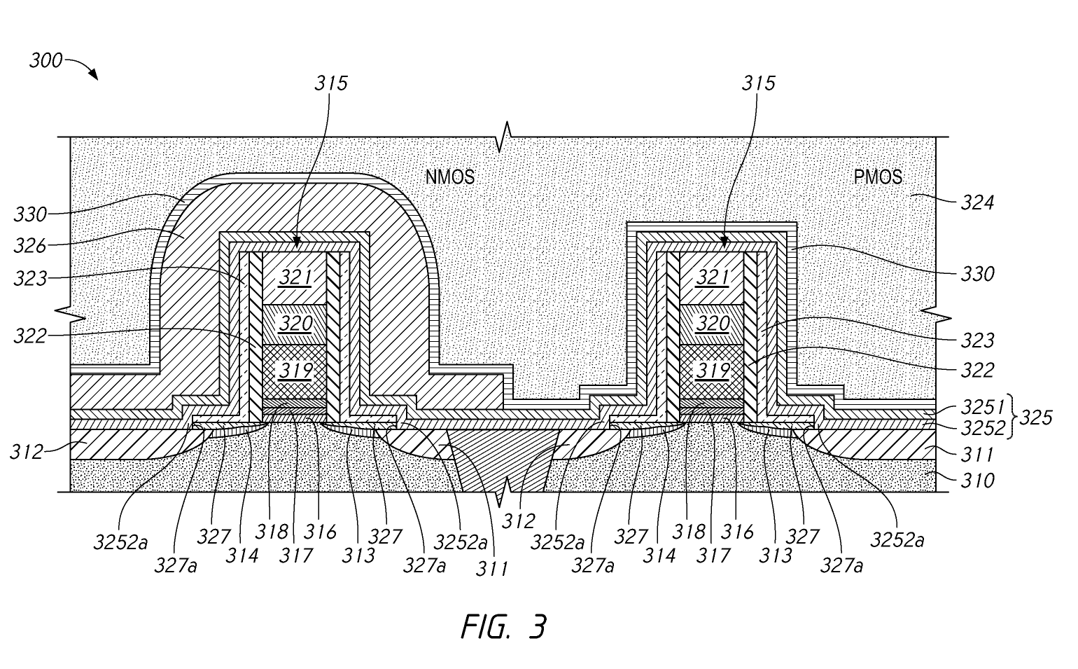

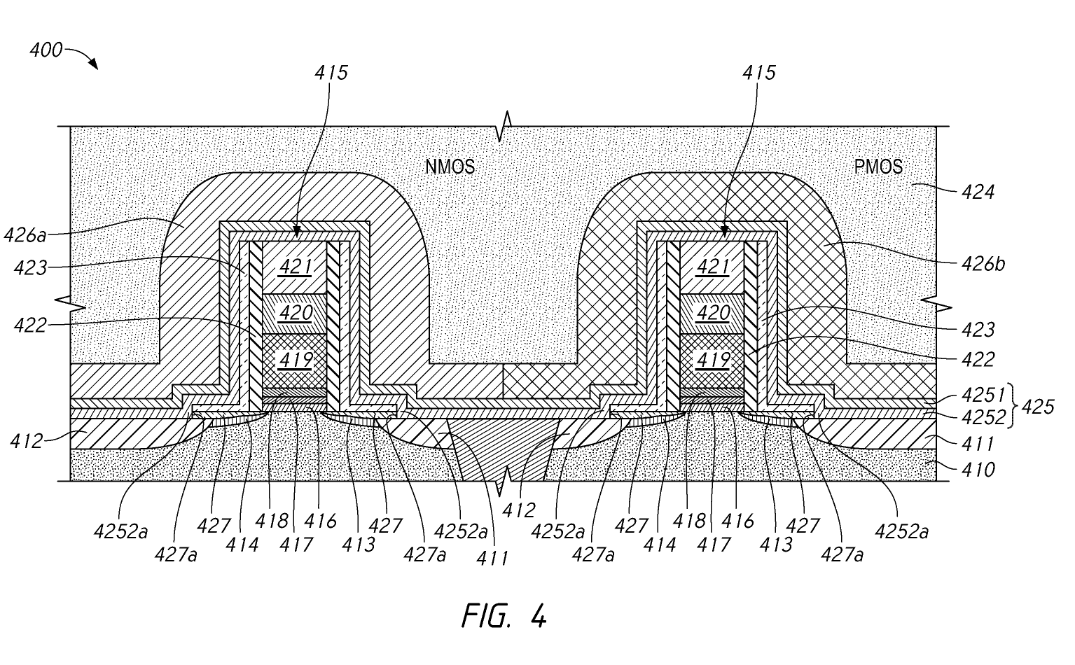

In some instances during device fabrication, such as high temperature processes (e.g., annealing), oxygen may leak from the oxide buffer layer 251 into the gate structure 15 (more specifically, the oxide buffer layer 16 below the metal gate layer 18 in the example configuration) through an oxygen path layer 27. This may negatively affect the temperature threshold-width (Vt-W) characteristic of a transistor, especially an NMOS transistor, leading to Local Layout Effect (LLE). In some embodiments, high temperature processes may be performed for forming interlayers 24 (FIG. 2), 324 (FIG. 3) and 424 (FIG. 4) and/or liners 330 (FIG. 3) (which will be described below) after the transistor structures are formed, and may cause oxygen to move from an oxygen source, such as the oxide buffer layer 251.

The oxygen path layer 27 may be formed under the gate structure 15 during device fabrication. For example, at least part of the oxygen path layer 27 may be generated during an etching process of the gate structure 15. At least another part of the oxygen path layer 27 may be generated during a plasma ashing process of the lightly-doped regions 13 and 14. At least still another part of the oxygen path layer 27 may be generated during a plasma ashing process of the active regions 11 and 12. The oxygen path layer 27 may include an oxide. The oxygen path layer 27 may be a silicon oxide layer, such as a silicon monoxide layer and a silicon dioxide layer. The silicon path layer 27 may be an oxygen permeable layer. The silicon path layer 27 thus generated may include an edge portion on one side that reaches the oxide buffer layer 16 above the lightly-doped regions 13 and 14 and another edge portion on an opposite side having a surface, such as a side surface 27a, exposed to the outside of the gate structure 15 between the second side wall 23 of the gate structure 15 and the active regions 11 and 12 of the semiconductor substrate 10. This forms an oxygen ingress path where oxygen can travel from one end and to the other end and enter the oxide buffer layer 16. In some embodiments, the oxygen path layer 27 may be generated by natural oxidation of air ambient, for example, before the formation of the first buffer layer 251.

In the present embodiments, the second buffer layer 252 that prevents ingress of oxygen from the first buffer layer 251 to the gate structure 15 is provided under the first buffer layer 251. The second buffer layer 252 includes a material capable of preventing the ingress of the oxygen to the gate structure 15. The second buffer layer 252 may include, for example, a nitride. In some embodiments, the second buffer layer 252 may include silicon nitride (SiN). In some embodiments, the second buffer layer 252 may include silicon oxynitride (SiON) or aluminium oxide (AlO). The second buffer layer 252 may include at least one of SiN, SiON, or AlO. These materials have low oxygen transmission rates or low oxygen permeability and are capable of keeping the oxygen from penetrating the second buffer layer 252. These materials may be oxygen impermeable materials and may not allow oxygen to pass through the second buffer layer 252. The second buffer layer 252 is provided between the first buffer layer 251 and the gate structure 15. The second buffer layer 252 may have a thickness thinner than the first buffer layer 251. As one example, the thickness of the first buffer layer 251 may be 70 angstrom whereas the thickness of the second buffer layer 252 may be in the range of 50 angstrom to 60 angstrom. The second buffer layer 252 prevents the oxygen ingress to the oxygen path layer 27 under the gate structure 15. The second buffer layer 252 covers the gate structure 15 and its double side wall 22, 23. The second buffer layer 252 includes a portion 252a that covers a surface, for example the exposed side surface 27a, of the oxygen path layer 27. In the depicted example, the second buffer layer 252 is formed along the second side wall 23 of the gate structure 15 and extends to the surface of the semiconductor substrate 10, more specifically at least to the surface of the active region 11. The portion 252a is located at a corner position to cover the surface 27a of the oxygen path/oxygen permeable layer 27 exposed under a lower horizontal portion of the second side wall 23 above the active region 11. The second buffer layer 252 acts as an oxygen barrier layer to disconnect or cut the oxygen ingress path (see FIG. 2) from the oxide, first buffer layer 251 of the layered buffer 25 through the oxygen permeable layer 27 to the oxide buffer layer 16 of the gate structure 15. The semiconductor device 1 including the oxygen impermeable, second buffer layer 252 under the oxide, first buffer layer 251 can effectively block the oxygen ingress path (see FIG. 2) and prevent or mitigate oxygen ingress into the gate stack structure 15 through the oxygen permeable layer 27, and hence improve the transistor Vt-W characteristic.

FIG. 3 depicts an example configuration of at least part of a semiconductor device 300 in a cross-sectional view according to some embodiments of the disclosure. The semiconductor device 300 is a CMOS device including an NMOS transistor and a PMOS transistor on a semiconductor substrate 310. The NMOS transistor and the PMOS transistor each correspond to the semiconductor device 1 in FIG. 1, except that while the NMOS transistor includes a tensile stressor layer 326 (e.g., 26 in FIG. 1), the PMOS transistor does not. In some embodiments, for the NMOS transistor, the layer 326 may be regarded as part of the side wall of the NMOS gate structure. As described above, the tensile stressor layer is removed from the PMOS transistor by for example dry etching with a first buffer layer 3251 (e.g., 251 in FIG. 1) acting as the etch stopper above a second buffer layer 3252 (e.g., 252 in FIG. 1). Furthermore, the semiconductor device 300 includes a liner 330 on both the NMOS and PMOS transistors. The liner 330 is provided between the NMOS and PMOS transistors and interlayers 324. The liner 330 may be for example a spin-on-dielectric (SOD) liner. The liner 330 may include for example a nitride material. In some embodiments, the liner 330 may include silicon nitride. In the NMOS transistor region, the liner 330 is provided on the tensile stressor layer 326. In the PMOS transistor region, the liner 330 is provided on the first buffer layer 3251 after the tensile stressor layer 326 is removed. Except for the above, the semiconductor substrate 310, active regions 311 and 312, lightly-doped regions 313 and 314, gate structures 315, oxide buffer layers 316, high-k layers 317, metal gate layers 318, silicon buffer layers 319, metal layers 320, cap layers 321, first side walls 322, second side walls 323, interlayers 324, layered buffers 325, first buffer layers 3251, second buffer layers 3252 (including portions 3252a thereof), the tensile stressor layer 326 at least on the NMOS transistor, and oxygen path layers 327 (including side surfaces 327a thereof) are the same or substantially the same as the corresponding components 10-27 in FIG. 1, respectively. The details thereof are thus omitted.

FIG. 4 depicts an example configuration of at least part of a semiconductor device 400 in a cross-sectional view according to some embodiments of the disclosure. The semiconductor device 400 is a CMOS device including an NMOS transistor and a PMOS transistor on a semiconductor substrate 410. The NMOS transistor and the PMOS transistor each correspond to the semiconductor device 1 in FIG. 1, except that while the NMOS transistor and the PMOS transistor both have tensile stressor layers 426a, 426b (e.g., 26 in FIG. 1) thereon, the tensile stressor layer 426b of the PMOS transistor includes heavy elements, such as germanium (Ge), Argon (Ar), and arsenic (As), implanted. In some embodiments, the layers 426a and 426b may be regarded as part of the side walls of the NMOS and PMOS transistors, respectively. The implantation of heavy elements may relax the strain caused by the tensile stressor layer 426b. Except for the above, the semiconductor substrate 410, active regions 411 and 412, lightly-doped regions 413 and 414, gate structures 415, oxide buffer layers 416, high-k layers 417, metal gate layers 418, silicon buffer layers 419, metal layers 420, cap layers 421, first side walls 422, second side walls 423, interlayers 424, layered buffers 425, first buffer layers 4251, second buffer layers 4252 (including portions 4252a thereof), the tensile stressor layer 426a on the NMOS transistor, and oxygen path layers 427 (including side surfaces 427a thereof) are the same or substantially the same as the corresponding components 10-27 in FIG. 1, respectively, or the corresponding components 310-327 in FIG. 3, respectively. The details thereof are thus omitted. In both semiconductor devices 300 and 400, the same or substantially the same advantages can be achieved as the semiconductor device 1, that is the effective blockage of the oxygen ingress path (see FIG. 2) through the oxygen permeable layers 327, 427 under the gate structures 315, 415 by the additional buffer layers as oxide barrier layers under the oxide buffer layers in the layered buffers 325, 425. This leads to improvement of the Vt-W characteristic of both NMOS and PMOS transistors, especially of the NMOS transistor.

DRAM is merely one example of a memory device, and the embodiments and the descriptions herein are not intended to be limited to DRAM. Memory devices other than DRAM, such as a static random-access memory (SRAM), a flash memory, an erasable programmable read-only memory (EPROM), a magnetoresistive random-access memory (MRAM), and a phase-change memory, can also be applied as the semiconductor memory device 1101. Furthermore, devices other than memory, including logic ICs, such as a microprocessor and an application-specific integrated circuit (ASIC), are also applicable as the semiconductor device according to the present embodiments.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still fall within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising:
a gate structure on a semiconductor substrate; and
a layered buffer on the gate structure, including:
a first buffer layer including an oxide; and
a second buffer layer under the first buffer layer, configured to prevent ingress of oxygen from the first buffer layer to the gate structure.

2. The apparatus according to claim 1, wherein the second buffer layer includes a material capable of preventing the ingress of the oxygen to the gate structure.

3. The apparatus according to claim 1, wherein the second buffer layer includes a nitride.

4. The apparatus according to claim 3, wherein the second buffer layer includes silicon nitride.

5. The apparatus according to claim 1, wherein the second buffer layer is configured to prevent the ingress of the oxygen to an oxygen path layer under the gate structure.

6. The apparatus according to claim 5, wherein the second buffer layer covers a surface of the oxygen path layer under the gate structure.

7. The apparatus according to claim 5, wherein the oxygen path layer is a silicon oxide layer.

8. The apparatus according to claim 1, wherein the first buffer layer is an etching stopper layer.

9. The apparatus according to claim 1, further comprising a tensile stressor layer on the layered buffer.

10. An apparatus, comprising:
a gate structure on a semiconductor substrate, the gate structure including a gate oxide layer under a gate metal layer; and
a layered buffer on the gate structure, including:
a first buffer layer including an oxide; and
a second buffer layer between the first buffer layer and the gate structure, the second buffer layer including a material that does not allow oxygen to pass therethrough and configured to cover a surface of another oxide layer under the gate structure.

11. The apparatus according to claim 10, wherein the material of the second buffer layer comprises a nitride.

12. The apparatus according to claim 10, wherein the other oxide layer under the gate structure reaches the gate oxide layer at one end and the second buffer layer at another end, and the second buffer layer includes a portion that covers the surface of the other oxide layer at the other end.

13. The apparatus according to claim 10, wherein the other oxide layer under the gate structure is a silicon oxide layer.

14. The apparatus according to claim 10, further comprising a tensile stressor layer on the layered buffer.

15. An apparatus, comprising:
a p-channel metal-oxide-semiconductor (PMOS) transistor and an n-channel metal-oxide-semiconductor (NMOS) transistor on a semiconductor substrate; and
an oxide layer on a gate stack structure of each of the PMOS and NMOS transistors; and
an oxygen barrier layer between the oxide layer and the gate stack structure, configured to prevent ingress of oxygen from the oxide layer to the gate structure.

16. The apparatus according to claim 15, wherein the oxygen barrier layer includes a material capable of keeping the oxygen from penetrating the oxygen barrier layer to an oxygen path layer under the gate structure.

17. The apparatus according to claim 16, wherein the material of the oxygen barrier layer comprises a nitride.

18. The apparatus according to claim 15, wherein the oxygen barrier layer covers a surface of an oxygen path layer under the gate structure.

19. The apparatus according to claim 15, further comprises a tensile stressor layer on the NMOS transistor.

20. The apparatus according to claim 15, wherein the oxide layer is a stopper layer for an etching process that removes a tensile stressor layer from the PMOS transistor.
